(19) United States
(12) Patent Application Publication
(10) Pub. No.: US 2020/0058704 A1
(43) Pub. Date: Feb. 20, 2020

(54) SELECTOR BASED ON TRANSITION METAL OXIDE AND PREPARATION METHOD THEREFOR

(71) Applicant: INSTITUTE OF MICROELECTRONICS, CHINESE ACADEMY OF SCIENCES, Beijing (CN)

(72) Inventors: Hangbing LV, Beijing (CN); Qing LUO, Beijing (CN); Xiaoxin XU, Beijing (CN); Shibing LONG, Beijing (CN); Qi LIU, Beijing (CN); Ming LIU, Beijing (CN)

(73) Assignee: INSTITUTE OF MICROELECTRONICS, CHINESE ACADEMY OF SCIENCES, Beijing (CN)

(21) Appl. No.: 16/486,614

(22) PCT Filed: Feb. 22, 2017
(86) PCT No.: PCT/CN2017/074401

§ 371 Date: Aug. 16, 2019

(51) Int. Cl. H01L 27/24; H01L 45/00

(52) U.S. Cl. CPC H01L 27/2418; H01L 45/1253; H01L 45/146; H01L 45/1233; H01L 45/1633

(57) ABSTRACT

A transition metal oxide based selector, a method for preparing the same and resistive random access memory are provided. The method comprises: S1, forming a tungsten plug on a transistor; S2, using the tungsten plug to function as a lower electrode, and preparing a transition metal layer on the tungsten plug; S3, oxidizing the transition metal layer to convert the transition metal layer into a transition metal oxide layer; and S4, depositing an upper electrode on the transition metal oxide, patterning the upper electrode and the transition metal oxide. The selector of the present disclosure may provide a high current density and has a good uniformity. The formed 1S1R structure may effectively eliminate crosstalk phenomenon in a resistive random access memory array, and effectively increase the storage density without increasing the storage unit area, thereby increasing device integration. In addition, the selector for the resistive random access memory of the present invention has advantages of a simple structure, easy for integration, a low cost, a good uniformity, and compatibility with a CMOS process.

### TECHNICAL FIELD

The present invention pertains to a technical field of integrated circuit manufacturing, and in particular relates to a transition metal oxide based selector, a method for preparing the same and resistive random access memory.

### BACKGROUND

Semiconductor memories may be classified into two categories, i.e., volatile memory and non-volatile memory, depending on whether they can maintain information stored therein when being powered down. With a popularity of portable electronic devices, share of non-volatile memory in the memory market is also increasing. The current FLASH technology prevails over the non-volatile memory market. However, the FLASH technology is encountering a series of bottleneck problems, such as a relatively large operating voltage, difficulty in reducing size, and maintaining time being not long enough. The resistive random access memory has become a research focus of new non-volatile memories due to its advantages such as a relatively low operating voltage, non-destructive reading, a relatively fast operation speed, a relatively simple structure and easy integration and the like. The resistive random access memory array (abbreviated as RRAM memory hereinafter) has a relatively serious crosstalk problem. A 2×2 cross-storage array is taken as an example hereinafter. Assuming that the memory device with coordinates (1, 1) is in a high-resistance state (HRS), and the rest three adjacent devices with coordinates (1, 2), (2, 2), and (2, 1) are in a low-resistance state (LRS) respectively. If a voltage is applied to a word line on which the device with coordinates (1,1) is located, the voltage will be conducted along a low resistance channel (2,1)→(2,2)→(1,2), thereby causing an erroneous reading, i.e., although the device with coordinates (1,1) is read to be in a low-resistance state (LRS), it is actually in a high-resistance state (HRS). Such crosstalk problems will become more serious as the array expands, seriously affecting the reliability of the RRAM memory and hindering its application.

Means for solving the crosstalk problem are a resistive random access memory (1T1R structure) with an integrated MOS transistor, a resistive random access memory with an external diode (1D1R structure), and a resistive random access memory (1S1R structure) connected in series with a selector. In the 1T1R structure, an area of the memory element mainly depends on an area of the transistor, which fails to take advantage of a relatively simple structure and a relatively small device area of the RRAM. The 1D1R is relatively weaker in terms of limiting the crosstalk current as compared with the 1S1R. In comparison, the 1S1R structure is currently a relatively ideal structure for solving crosstalk problems.

However, most of the current selectors of related art are not capable of being compatible with CMOS, few of which may simultaneously have compatible advantages such as a relatively high current density, a relatively high selection ratio, and a relatively high durability and the like. Moreover, a relatively poor homogeneity/uniformity is a problem existing in most current selectors. In terms of solving the problem of the crosstalk in RRAM array and putting the RRAM array into application, it is necessary to provide selectors each having a relatively high performance, a relatively good uniformity and a relatively superior reliability and being compatible with a standard CMOS processes.

### SUMMARY

A technical problem to be solved by the present disclosure is to overcome the crosstalk problem in the RRAM array.

In order to solve the above technical problem, the present invention provides a method for preparing a transition metal oxide-based selector, comprising steps of:

S1, forming a tungsten plug on a transistor;

S2, using the tungsten plug to function as a lower electrode, and preparing a transition metal layer on the tungsten plug;

S3, oxidizing the transition metal layer to convert the transition metal layer into a transition metal oxide layer; and

S4, depositing an upper electrode on the transition metal oxide, patterning the upper electrode and the transition metal oxide.

According to a preferred embodiment of the present invention, the transition metal is at least one of Ta, Ti, Zr, Hf, and Nb.

According to a preferred embodiment of the present invention, the transition metal layer has a thickness in a scope from 2 nm to 8 nm.

According to a preferred embodiment of the present invention, the transition metal layer is converted into a transition metal oxide layer by an annealing treatment is performed in step S3.

According to a preferred embodiment of the present invention, the annealing treatment is performed in a plasma oxygen environment.

According to a preferred embodiment of the present invention, the annealing treatment is performed under conditions of a temperature in a scope from 350 degrees Celsius to 400 degrees Celsius and a time in a scope from 60 seconds to 400 seconds.

According to a preferred embodiment of the present invention, the transition metal oxide formed has a trapezoidal energy band.

According to a preferred embodiment of the present invention, the upper electrode is made of at least one of Pt, W, Ru, Al, TiN, TaN, IrO₂, ITO, and IZO.

The present invention also provides a transition metal oxide-based selector prepared by above method.

The present invention also provides a resistive random access memory comprising the transition metal oxide-based selector. Preferably, the resistive random access memory is in a 1S1R structure. Preferably, the resistive random access memory is in a 1S1R structure. With the above technical solutions, the present invention has the following advantageous effects:

1. The solution of the present invention has a relatively simple preparation process and a relatively low process cost, and is favorable for integration of memory devices.

2. The present invention may provide a bidirectional rectifying device for a bipolar resistive random access memory in the 1S1R structure, suppressing the reading crosstalk.

3. The present invention may provide a relatively higher current density and a relatively higher selection ratio for the 1S1R structure bipolar resistive random access memory, which is advantageous for an even larger scale of integration of the RRAM.

4. The present invention may provide a selector compatible with a standard CMOS process for a bipolar resistive random access memory in a 1S1R structure, facilitating industrial production.

5. The present invention may provide a selector having an ultra-high uniformity for a bipolar resistive random access memory, which reduces the difficulty in circuit design and facilitates industrial production and application.

### BRIEF DESCRIPTION OF THE DRAWINGS

FIG. 1 is a schematic view showing a method for preparation of a selector provided by the present invention;

FIGS. 2 to 5 are schematic views showing the method for preparation of the selector;

FIG. 6 is a schematic diagram of a principle of the selector provided by the present invention;

FIG. 7 is a practically measured profile of current vs. voltage of the selector provided by the present invention; and

FIG. 8 is a practically measured profile of current vs. voltage of the resistive random access memory connected with a selector provided by the present invention.

### DETAILED DESCRIPTION OF EMBODIMENTS

The method for preparing a transition metal oxide-based selector provided by the present invention, comprises steps of:

S1, Forming a Tungsten Plug on a Transistor

In this step, a tungsten plug may be formed by a standard CMOS process, which specifically includes processes such as forming a tungsten plug hole, depositing a diffusion barrier layer, filling the hole by a PECVD process, and chemical on-board polishing and the like.

S2, Using the Tungsten Plug to Function as a Lower Electrode, and Preparing a Transition Metal Layer on the Tungsten Plug

In this step, a transition metal layer may be grown on the tungsten plug by magnetron sputtering, and the transition metal may be Ta, Ti, Zr, Hf, Nb, etc., and the layer has a thickness in a scope from 2 nm to 8 nm. Since the lower electrode of the present invention is a tungsten plug, it is not necessary to prepare a lower electrode in particular.

S3, Oxidizing the Transition Metal Layer to Convert the Transition Metal Layer into a Transition Metal Oxide Layer

In this step, a transition metal oxide may be formed by annealing the device. An annealing environment may be plasma oxygen environment with an annealing temperature from 350 degrees to 400 degrees (being compatible with the CMOS process). The annealing time depends on the thickness of the transition metal layer(the thicker the longer in the time), and the annealing time is 300 s in the case where the oxidation temperature is 400 degrees upon taking 8 nm as an example.

S4, Depositing an Upper Electrode on the Transition Metal Oxide

The upper electrode may be of a material such as W, Ru, Al, and Ti and the like, or may be a conductive metal compound such as TiN, TaN, IrO₂, ITO, IZO. The upper electrode material may be prepared by one of electron beam evaporation, chemical vapor deposition, pulsed laser deposition, atomic layer deposition, and sputtering. Its thickness is generally 30 nm to 200 nm.

This step may be followed by a step of patterning the upper electrode and the transition metal oxide.

In order to make the objects, technical solutions and advantages of the present invention more clear, the present invention will be further described in detail below with reference to the specific embodiments of the invention. In the drawings, the thicknesses of layers and regions are exaggerated for clarity, but they merely serve as a schematic diagram which should not be considered to strictly reflect the proportional relationship of geometric dimensions.

The drawings are a schematic representation of an idealized embodiment of the present invention, and the illustrated embodiments of the present invention should not be considered to be limited to the specific shapes of the regions shown in the drawings, but include the resulting shapes, e.g., a resulting shape including deviations caused by the manufacturing. For example, the curve obtained by a dry etching generally has the characteristics of being curved or rounded, but in the illustrations of the embodiments of the present invention, either of them is represented by rectangles, and the illustrations in the figures are schematic, which should not be considered as limiting the scope of the present invention.

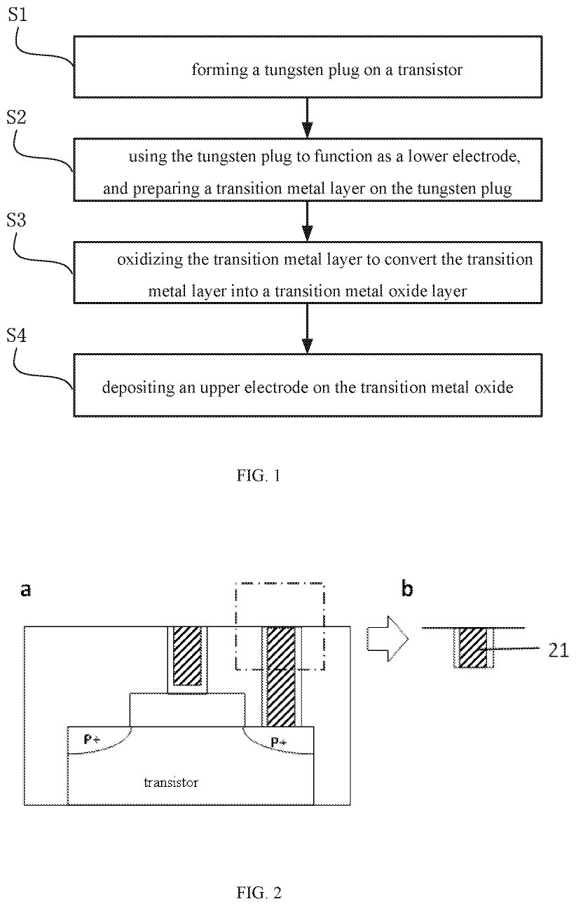

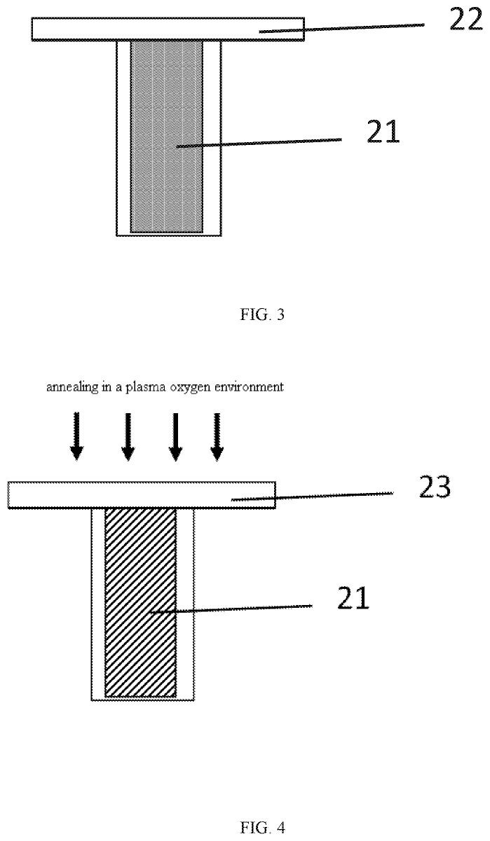

FIG. 1 is a schematic flow chart showing a method for preparation a transition metal oxide-based selector provided by the present invention. Meanwhile, FIG. 2 to FIG. 5 respectively illustrate schematic structures in each step of the method for manufacturing the resistive random access memory. Hereinafter, the method for manufacturing the resistive random access memory will be described in detail with reference to FIGS. 1 to 5.

As shown in the figures, the preparation method of the embodiment of the present invention mainly includes:

S1, forming a tungsten plug on the transistor.

In this step, a tungsten plug may be formed by a standard CMOS process, and the following sub-steps are included specifically:

S11, forming a tungsten plug hole above the MOS device by a photolithography and an etching process

S12, depositing a diffusion barrier layer in the tungsten plug hole, the diffusion barrier layer in this embodiment being a Ti/TiN compound layer, or a Ti layer and a TiN layer, and having a thickness ranging from 3 nm to 50 nm.

S13, filling the hole with metal tungsten using a PECVD process, the thickness of the tungsten is 50-5000 nm.

S14, chemically polishing the surface of the tungsten plug.

Part ‘a’ of FIG. 2 shows a sectional view of the finished tungsten plug which is subjected to a conventional CMOS process. Subsequent processing steps are performed on the upper surface of the tungsten plug 21 shown in part ‘b’ of FIG. 2.

S2, using the tungsten plug as a lower electrode, and preparing a transition metal layer on the tungsten plug

In this step, the transition metal layer 22 may be grown on the tungsten plug 21 by magnetron sputtering, and the transition metal may be Ta, Ti, Zr, Hf, Nb, etc., and the layer has a thickness in a scope from 2 nm to 8 nm. Since the lower electrode of the present invention is a tungsten plug, it is not necessary to prepare a lower electrode in particular.

S3, oxidizing the transition metal layer to convert the transition metal layer into a transition metal oxide layer.

In this step, as shown in FIG. 4, the transition metal layer is converted into a transition metal oxide layer 23 by annealing the device in a plasma oxygen environment. The annealing conditions are: (1) the temperature is between 350 degrees Celsius to 400 degrees Celsius. (2) the time is from 60 seconds to 400 seconds (depending on the oxidation temperature and the thickness of the transition metal). (3) Environment: plasma oxygen gas. The transition metal oxide is rapidly annealed and oxidized in the environment of plasma oxygen. The oxidation process is performed from outside to inside, the surface oxidation is more thoroughly to obtain a fully oxidized transition metal oxide, and the transition metal oxide with a lower valence state is created at a distance farther away from the surface. Due to the different band gaps of the transition metal oxides of different components (the more sufficient the oxidation is, the wider the band gap is), an energy band in a shape of trapezoid is formed.

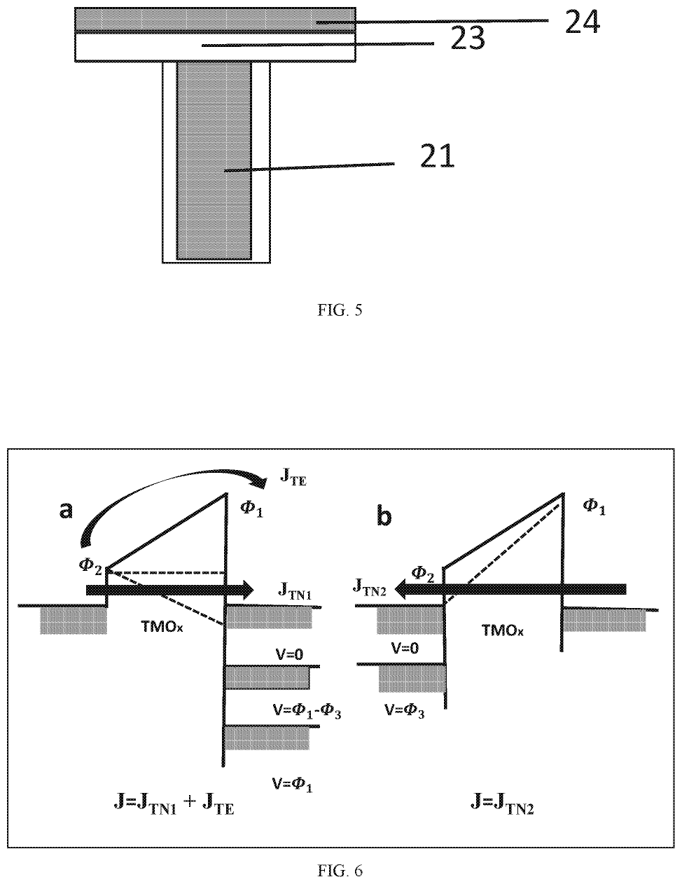

FIG. 6 shows the energy band diagram of the transition metal oxide layer. As shown in the figure, the energy band of the transition metal oxide layer is trapezoidal, and such an energy band structure results in a non-linear relationship between current and voltage. As shown in the diagram ‘a’ of FIG. 6, when a forward voltage is applied, a tunneling current prevails in a condition that the value of voltage is relatively small. Since the device is relatively thick, then the tunneling current is relatively small. In a condition that the forward current is relatively large, the current is mainly excited by hot electrons and the current is sharply increased, thereby forming a high nonlinearity. As shown in diagram ‘b’ of FIG. 6, when a reverse voltage is applied, due to a relatively high barrier, the current excited by hot electrons is relatively small, resulting in the reverse current density being smaller than the forward current density.

S4, depositing an upper electrode on the transition metal oxide.

In such an embodiment, as shown in FIG. 5, the upper electrode 24 is made of at least one of Pt, W, Ru, Al or a conductive metal compound TiN, TaN, IrO₂, ITO, IZO. As for the step of patterning the upper electrode, it may be performed by conventional semiconductor photolithography and etching.

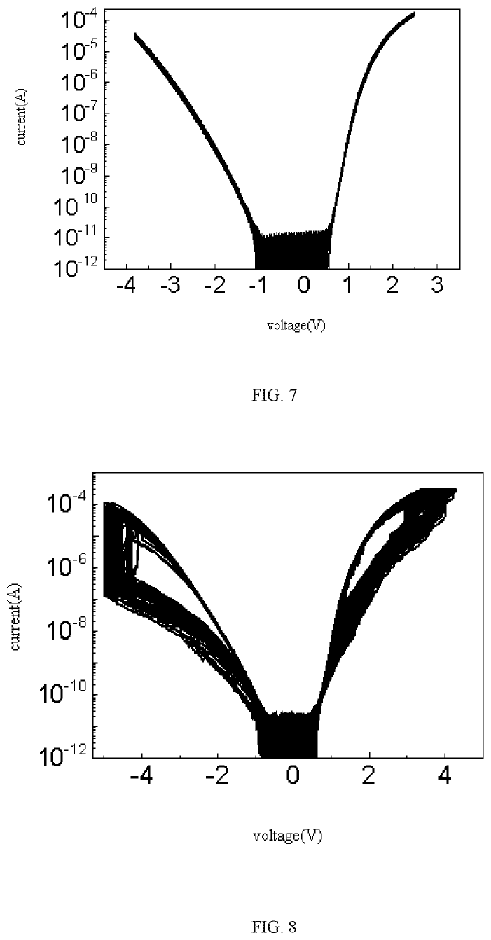

FIG. 7 is a practically measured profile of current vs. voltage of the transition metal oxide-based selector provided by the present invention. The device is subjected to voltage scan for 1000 times, and it is found that the uniformity of the device is very good.

FIG. 8 is a practically measured profile of current vs. voltage of a resistive device provided by the present invention, it is proven that the device may operate normally in an array with 1S1R structures, and it shows as an example the basic properties of this type of selector.

In summary, the PECVD is utilized in the present invention to oxidize the transition metal to form a transition metal oxide, which is followed by growth of the upper electrode. The transition metal oxide-based selector of the present invention may provide a relatively higher current density and has a good uniformity, and the 1S1R structure thus formed may effectively suppress the crosstalk phenomenon in the resistive random access memory array and effectively increase storage density without increasing area of the memory element area and improve device integration. In addition, the selector for the resistive random access memory of the invention has advantages of simple structure, easy integration, low cost, good uniformity, compatibility with the CMOS process, and the like, and is beneficial to an extensive promotion of application of the present invention.

The specific embodiments of the present invention have been described in detail in the foregoing detailed description of the embodiments of the present invention. All modifications, equivalents, improvements, etc., made within the spirit and scope of the present invention is intended to be included within the scope of the invention.

1. A method for preparing a transition metal oxide-based selector, comprising steps of:
S1, forming a tungsten plug on a transistor;
S2, using the tungsten plug to function as a lower electrode, and preparing a transition metal layer on the tungsten plug;
S3, oxidizing the transition metal layer to convert the transition metal layer into a transition metal oxide layer; and
S4, depositing an upper electrode on the transition metal oxide layer, patterning the upper electrode and the transition metal oxide.

2. The method according to claim 1, wherein the transition metal is at least one of Ta, Ti, Zr, Hf, and Nb.

3. The method according to claim 2, wherein the transition metal layer has a thickness in a scope from 2 nm to 8 nm.

4. The method according to claim 1, wherein in step S3, the transition metal layer is converted into a transition metal oxide layer by an annealing treatment.

5. The method according to claim 4, wherein the annealing treatment is performed in a plasma oxygen environment.

6. The method according to claim 5, wherein the annealing treatment is performed under conditions of a temperature in a scope from 350 degrees Celsius to 400 degrees Celsius and a time in a scope from 60 seconds to 400 seconds.

7. The method according to claim 4, wherein the transition metal oxide formed has a trapezoidal energy band.

8. The method according to claim 1, wherein the upper electrode is made of at least one of Pt, W, Ru, Al, TiN, TaN, IrO₂, ITO, and IZO.

9. A transition metal oxide-based selector prepared by the method according to claim 1.

10. A resistive random access memory comprising the transition metal oxide-based selector according to claim 9.
